(19) United States
(12) Patent Application Publication
(10) Pub. No.: US 2024/0387750 A1
(43) Pub. Date: Nov. 21, 2024

(54) SEMICONDUCTOR DEVICE

(71) Applicant: Nuvoton Technology Corporation, Hsinchu Science Park (TW)

(72) Inventor: Po-An CHEN, Toufen City (TW)

(21) Appl. No.: 18/422,890

(22) Filed: Jan. 25, 2024

(30) Foreign Application Priority Data
May 18, 2023 (TW) 112118429

(51) Int. Cl. H01L 29/861; H01L 29/06; H01L 29/40; H01L 29/417; H01L 29/778

(52) U.S. Cl. CPC H01L 29/861; H01L 29/06; H01L 29/402; H01L 29/41775; H01L 29/778

(57) ABSTRACT

A semiconductor device is provided. The semiconductor device includes a substrate, a channel layer, a barrier layer, a gate electrode, a dielectric layer, a source electrode, a drain electrode, and a diode structure. The channel layer is disposed on the substrate. The barrier layer is disposed on the channel layer. The gate electrode is disposed on the barrier layer. The dielectric layer is disposed on the gate electrode. The source electrode and the drain electrode are disposed on opposite sides of the gate electrode and in contact with the channel layer, respectively. The diode structure is disposed on the dielectric layer and is electrically connected to the source electrode.

### CROSS REFERENCE TO RELATED APPLICATIONS

This application claims priority of Taiwan Patent Application No. 112118429, filed on May 18, 2023, the entirety of which is incorporated by reference herein.

### BACKGROUND OF THE INVENTION

### Field of the Invention

The present invention relates to a semiconductor device, and, in particular, to a semiconductor device that includes a diode structure.

### Description of the Related Art

Because gallium nitride (GaN) material has a wide band-gap and a strong polarization effect, and it is widely used. For example, gallium nitride-based semiconductors are widely used in high electron mobility transistors (HEMT) that have a heterojunction structure.

However, in these high electron mobility transistors, there may be problems with insufficient conduction efficiency and high power loss. Although existing semiconductor devices have gradually met their intended uses, they have not yet fully met requirements in all respects. Therefore, there are still some problems to be overcome with respect to semiconductor devices.

### BRIEF SUMMARY OF THE INVENTION

The semiconductor device of the present disclosure includes a high electron mobility transistor (HEMT) and a diode structure disposed on the high electron mobility transistor, so as to reduce power loss in a reverse conduction state. Furthermore, since the diode structure is disposed in the normal direction of the substrate of the high electron mobility transistor, the overall area of the semiconductor device may be reduced, which is beneficial to increase the device density.

In some embodiments of the present disclosure, a semiconductor device is provided. The semiconductor device includes a substrate, a channel layer, a barrier layer, a gate electrode, a dielectric layer, a source electrode, a drain electrode, and a diode structure. The channel layer is disposed on the substrate. The barrier layer is disposed on the channel layer. The gate electrode is disposed on the barrier layer. The dielectric layer is disposed on the gate electrode. The source electrode and the drain electrode are disposed on opposite sides of the gate electrode and in contact with the channel layer, respectively. The diode structure is disposed on the dielectric layer and electrically connected with the source electrode.

The semiconductor device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic cross-sectional view of a semiconductor device according to an embodiment of the present disclosure.

FIG. 2 is a schematic top view of a semiconductor device according to an embodiment of the present disclosure.

FIG. 3 is a circuit diagram of a semiconductor device according to an embodiment of the present disclosure.

FIG. 4 is a schematic cross-sectional view of a semiconductor device according to an embodiment of the present disclosure.

FIG. 5 is a schematic cross-sectional view of a semiconductor device according to an embodiment of the present disclosure.

FIG. 6 is a schematic top view of a semiconductor device according to an embodiment of the present disclosure.

FIG. 7 is a schematic cross-sectional view of a semiconductor device according to an embodiment of the present disclosure.

FIG. 8 is a schematic cross-sectional view of a semiconductor device according to an embodiment of the present disclosure.

FIG. 9 is a schematic top view of a semiconductor device according to an embodiment of the present disclosure.

### DETAILED DESCRIPTION OF THE INVENTION

Semiconductor devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simple and clear description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings are turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguish an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is, there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the following embodiments, features in several different embodiments may be replaced, recombined, and bonded to complete other embodiments without departing from the spirit of the present disclosure. The features of the various embodiments can be used in any combination as long as they do not violate the spirit of the present disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (thickness direction). In some embodiments, the schematic cross-sectional views described herein are schematic views of the YZ plane (a plane formed by the first direction D1 and the third direction D3), and the schematic top views described herein are schematic views of the XY plane (a plane formed by the first direction D1 and the second direction D2). In some embodiments, the normal direction of the substrate described herein is the third direction D3.

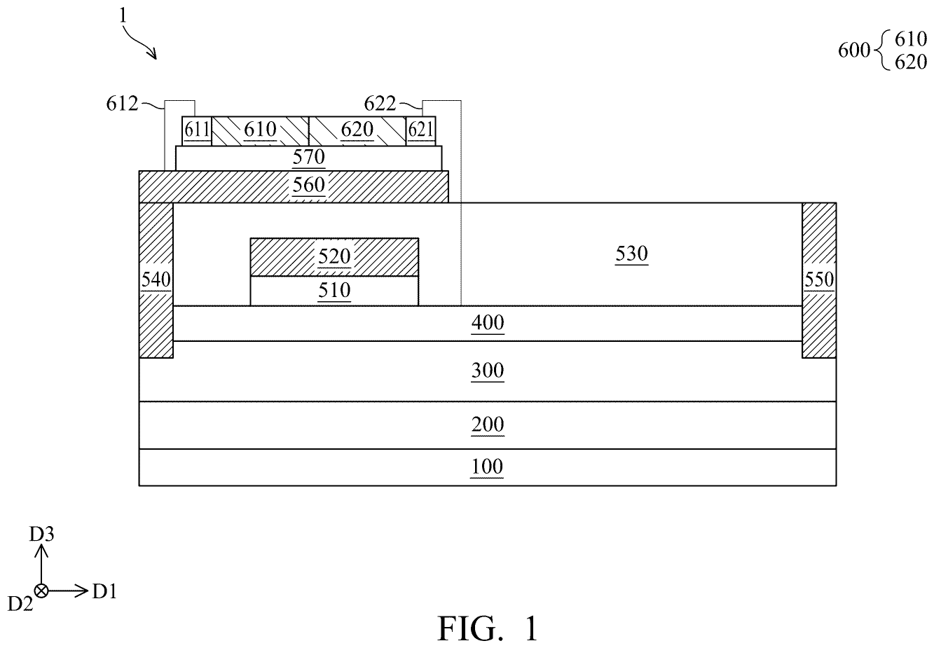

Referring to FIG. 1, it is a schematic cross-sectional view of a semiconductor device 1 according to an embodiment of the present disclosure. In some embodiments, the semiconductor device 1 may include a substrate 100, a channel layer 300, a barrier layer 400, a gate electrode 520, a dielectric layer 530, a source electrode 540, a drain electrode 550, and a diode structure 600. In some embodiments, the substrate 100 is provided, the channel layer 300 is formed on the substrate 100, and the barrier layer 400 is formed on the channel layer 300.

In some embodiments, the substrate 100 may include a bulk semiconductor substrate, a semiconductor-on-insulator (SOI) substrate, or the like. In general, a semiconductor-on-insulator substrate includes a semiconductor layer formed on an insulator. For example, the insulator may include silicon oxide, silicon nitride, polysilicon, or a combination thereof, and the semiconductor layer may include silicon, aluminum nitride (AlN) or the like. In some embodiments, the substrate 100 may be an undoped substrate or a doped substrate, for example, a substrate doped with p-type dopant or n-type dopant. In some embodiments, the substrate 100 may be a multi-layered substrate or a gradient substrate. In some embodiments, the substrate 100 may be a semiconductor substrate or a ceramic substrate, for example, a gallium nitride (GaN) substrate, a silicon carbide (SiC) substrate, an aluminum nitride substrate, or a sapphire substrate. In some embodiments, the substrate 100 may be a silicon substrate.

In some embodiments, the channel layer 300 may include III-V group compound semiconductor material, for example, a III group nitride, but the present disclosure is not limited thereto. For example, the channel layer 300 may include gallium nitride, aluminum gallium nitride (AlGaN), aluminum indium nitride (AlInN), indium gallium nitride (InGaN), indium aluminum gallium nitride (InAlGaN), the like, or a combination thereof, but the present disclosure is not limited thereto. In some embodiments, the channel layer 300 may be formed by a deposition process, and the deposition process may be chemical vapor deposition (CVD), atomic layer deposition (ALD), molecular beam epitaxy (MBE), liquid phase epitaxy (LPE), the like, or a combination thereof, but the present disclosure is not limited thereto. In some embodiments, the channel layer 300 may include gallium nitride.

In some embodiments, the barrier layer 400 may include a III-V group compound semiconductor material, for example, a III group nitride. For example, the barrier layer 400 may be or include aluminum nitride, aluminum gallium nitride, aluminum indium nitride, indium aluminum gallium nitride, the like, or a combination thereof, but the present disclosure is not limited thereto. In some embodiments, the barrier layer 400 may be formed by the deposition process. In some embodiments, the barrier layer 400 may include aluminum gallium nitride. In some embodiments, since there is a heterogeneous interface between gallium nitride as the channel layer 300 and aluminum gallium nitride as the barrier layer 400, and there is a difference in lattice constant between the channel layer 300 and the barrier layer 400, the two-dimensional electron gas (2DEG) is formed near the top surface of the channel layer 300. In some embodiments, the two-dimensional electron gas is formed in the channel layer 300 and is adjacent to the barrier layer 400. In some embodiments, the two-dimensional electron gas may serve as a current path for high electron mobility transistors.

In some embodiments, a buffer layer 200 may be further formed between the substrate 100 and the channel layer 300 to reduce lattice dislocation between the substrate 100 and the channel layer 300, so as to reduce defects. In some embodiments, the buffer layer 200 may include a III-V group compound semiconductor material, for example, a III group nitride. For example, the buffer layer 200 may include gallium nitride, aluminum nitride, aluminum gallium nitride, aluminum indium nitride, the like, or a combination thereof, but the present disclosure is not limited thereto. In some embodiments, the buffer layer 200 may be formed by the deposition process.

In some embodiments, a nucleation layer (not shown) may be further disposed between the substrate 100 and the buffer layer 200 to reduce the lattice dislocation between the substrate 100 and other layers disposed on the substrate 100, thereby improving epitaxy quality and reliability. In some embodiments, the nucleation layer may include aluminum nitride, aluminum gallium nitride, the like, or a combination thereof, but the present disclosure is not limited thereto. In some embodiments, the nucleation layer may be formed by the deposition process.

As shown in FIG. 1, in some embodiments, a compound semiconductor layer 510 may be formed on the barrier layer 400, so that the compound semiconductor layer 510 may be disposed between the barrier layer 400 and the subsequently formed gate electrode 520. In some embodiments, the compound semiconductor layer 510 may be doped with p-type dopants. In some embodiments, the compound semiconductor layer 510 may include p-type doped gallium nitride (p-GaN). Since the compound semiconductor layer 510 can suppress the formation of the two-dimensional electron gas under the compound semiconductor layer 510, the two-dimensional electron gas becomes a depleted region.

Therefore, disposing the compound semiconductor layer 510 can enable the high electron mobility transistor to be in a normally-off state, thereby serving as an enhancement mode (E mode) high electron mobility transistor. Thus, the semiconductor device of the present disclosure is suitable for enhancement mode high electron mobility transistors. In other words, the present disclosure can omit field effect transistors (for example, metal oxide semiconductor field effect transistors, MOSFETs) used to be connected with depletion mode (D mode) high electron mobility transistors.

In some embodiments, the gate electrode 520 is formed on the barrier layer 400. Specifically, the gate electrode 520 is formed on the compound semiconductor layer 510. In some embodiments, the gate electrode 520 may include a conductive material, for example, the conductive material may include metal, metal nitride, semiconductor material, the like, or a combination thereof, but the present disclosure is not limited thereto. In some embodiments, the metal may include gold (Au), nickel (Ni), platinum (Pt), palladium (Pd), iridium (Ir), titanium (Ti), chromium (Cr), tungsten (W), aluminum (Al), copper (Cu), titanium nitride (TiN), the like, or a combination thereof, but the present disclosure is not limited thereto. The semiconductor material may include polysilicon or polycrystalline germanium. The conductive material may be formed by chemical vapor deposition, sputtering, resistive heating evaporation, electron beam evaporation, the like, or a combination thereof, but the present disclosure is not limited thereto. In some embodiments, the gate electrode 520 may be a Schottky contact.

In some embodiments, a dielectric layer 530 is formed on the gate electrode 520 to cover the top surface and the side surface of the gate electrode 520 and the side surface of the compound semiconductor layer 510. In some embodiments, the dielectric layer 530 may include an oxide such as silicon oxide, a nitride such as silicon nitride, an oxynitride such as silicon oxynitride, the like, or a combination thereof, but the present disclosure is not limited thereto. In some embodiments, the dielectric layer 530 may have a thickness greater than or equal to 1 μm in the normal direction of the substrate 100 (that is, the third direction D3). For example, the thickness of the dielectric layer 530 may be 1 μm, 1.5 μm, 2 μm, 2.5 μm, 3 μm, 5 μm, 10 μm, or any value between the foregoing values or a value range composed of the foregoing values, but the present disclosure is not limited thereto. If the thickness of the dielectric layer 530 is less than 1 μm, the electrical isolation between the gate electrode 520 and the subsequently formed diode structure 600 may be insufficient.

In some embodiments, the source electrode 540 and the drain electrode 550 are respectively formed on opposite sides of the gate electrode 520, and the source electrode 540 and the drain electrode 550 are respectively in contact with the channel layer 300. In some embodiments, the material and formation method of the source electrode 540 and the drain electrode 550 may be the same as or different from the material and formation method of the gate electrode 520. In some embodiments, the source electrode 540 is formed on one side of the gate electrode 520 and the drain electrode 550 is formed on the other side of the gate electrode 520. In some embodiments, the source electrode 540 and the drain electrode 550 may pass through (penetrate) the dielectric layer 530 and the barrier layer 400, so that the source electrode 540 and the drain electrode 550 are in contact with the channel layer 300. In some other embodiments, the source electrode 540 and the drain electrode 550 may pass through the dielectric layer 530 but do not need to pass through the barrier layer 400, so that the source electrode 540 and the drain electrode 550 are in contact with the channel layer 300.

In some embodiments, after the formation of the compound semiconductor layer 510, the gate electrode 520, and the dielectric layer 530, the source electrode 540 and the drain electrode 550 passing through the dielectric layer 530 and the barrier layer 400 are formed. In other embodiments, after the formation of the compound semiconductor layer 510, the source electrode 540 and the drain electrode 550 passing through the barrier layer 400 are formed. Next, the gate electrode 520 is formed on the compound semiconductor layer 510, and the dielectric layer 530 is formed on the gate electrode 520, the compound semiconductor layer 510, the source electrode 540, and the drain electrode 550.

In some embodiments, a source field plate 560 is formed on the dielectric layer 530, and the source field plate 560 is electrically connected to the source electrode 540. In some embodiments, the material and formation method of the source field plate 560 may be the same as or different from the material and formation method of the source electrode 540. In some embodiments, the source field plate 560 may be disposed between the source electrode 540 and the drain electrode 550. In some embodiments, the source field plate 560 may be closer to the source electrode 540 than to the drain electrode 550. In some embodiments, the projection of the gate electrode 520 on the substrate 100 is located within the projection of the source field plate 560 on the substrate 100. In some embodiments, the source field plate 560 may cover the gate electrode 520 in the normal direction of the substrate 100. For example, in the normal direction of the substrate 100, the source field plate 560 may completely cover the gate electrode 520. Accordingly, the charge distribution may be adjusted by the source field plate 560.

As shown in FIG. 1, in some embodiments, an insulating layer 570 is formed on the source field plate 560 to provide electrical isolation between the source field plate 560 and the subsequently formed diode structure 600. In some embodiments, the material and formation method of the insulating layer 570 may be the same as or different from the material and formation method of dielectric layer 530. In some embodiments, the insulating layer 570 may include oxide such as silicon oxide, nitride such as silicon nitride, oxynitride such as silicon oxynitride, the like, or a combination thereof, but the present disclosure is not limited thereto. In some embodiments, the insulating layer 570 may be a second dielectric layer or may be an extending portion of the dielectric layer 530.

In other embodiments, such as embodiments in which the insulating layer 570 is the extending portion of the dielectric layer 530, the source field plate 560 may be embedded in the dielectric layer 530. In the present embodiment, a side surface of the source field plate 560 may be in contact with a side surface of the source electrode 540. In the present embodiment, the dielectric layer 530 may cover the top surface of the source field plate 560 and expose the top surface of the source electrode 540. In the present embodiment, the exposed top surface of the source electrode 540 is used to electrically connect with the subsequently formed diode structure 600. For example, the source electrode 540 is electrically connected to the diode structure 600 by the subsequently formed first connecting member 612. In the present embodiment, the material of the insulating layer 570 is the same as the material of the dielectric layer 530.

As shown in FIG. 1, in some embodiments, a diode structure 600 is formed on the dielectric layer 530, and the diode structure 600 may be electrically connected to the source electrode 540. In some embodiments, the diode structure 600 may be closer to the source electrode 540 than to the drain electrode 550. In some embodiments, the diode structure 600 may be formed on the insulating layer 570. Therefore, in the case that the diode structure 600 is formed on the insulating layer 570, the reliability of the diode structure 600 may be improved since the material of the diode structure 600 may be directly deposited on the insulating layer 570 (for example, both of the diode structure 600 and the insulating layer 570 include silicon-based material). Furthermore, the insulating layer 570 may provide electrical isolation between the diode structure 600 and the source field plate 560.

In some embodiments, the source field plate 560 may be disposed between the diode structure 600 and the gate electrode 520 in the normal direction of the substrate 100. In some embodiments, the projection of the diode structure 600 on the substrate 100 is located within the projection of the source field plate 560 on the substrate 100. Accordingly, by adjusting the position and size of the source field plate 560, the diode structure 600 is prevented from affecting the electrical characteristics of the gate electrode 520. In detail, since the source field plate 560 may cover the bottom surface of the diode structure 600, the source field plate 560 can prevent the diode structure 600 from affecting the gate electrode 520 under the diode structure 600 in the conduction state.

In some embodiments, the diode structure 600 may be a P-N junction diode, a P-I-N diode, a Schottky diode, or a combination thereof. In some embodiments, the diode structure 600 may include polysilicon. In some embodiments, the diode structure 600 may be formed by an epitaxial process or a furnace process. In some embodiments, the polysilicon may be deposited on the source field plate 560 (specifically, on the insulating layer 570) by the epitaxial process, and then an implantation process is performed to dope the polysilicon, thereby forming the diode structure 600. In some embodiments, in the present disclosure, the buffer layer 200, the channel layer 300, and the barrier layer 400 may be formed by the epitaxial process, and then the gate electrode 520, the source electrode 540, the drain electrode 550, and the source field plate 560 may be formed by a metallization process such as sputtering or evaporation process, and then the diode structure 600 may be formed by the epitaxial process. In other words, in the present disclosure, the first epitaxial process for forming the channel layer 300 and the barrier layer 400 may be performed, and then the metallization process may be performed. Then, the second epitaxial process for forming the diode structure 600 may be performed after preforming the metallization process.

In some embodiments, the diode structure 600 may at least partially overlap the gate electrode 520 in the normal direction of the substrate 100. For example, in the normal direction of the substrate 100, the diode structure 600 may completely overlap the gate electrode 520. In some embodiments, in the normal direction of the substrate 100, the diode structure 600 may expose a portion of the gate electrode 520, and the exposed portion of the gate electrode 520 may be closer to the source electrode 540 than to the drain electrode 550. In some embodiments, the projection of the diode structure 600 on the substrate 100 at least partially overlaps the projection of the gate electrode 520 on the substrate 100.

As shown in FIG. 1, the diode structure 600 may be the P-N junction diode as an example for illustration, but the present disclosure is not limited thereto. In some embodiments, the diode structure 600 may include a first semiconductor block 610 and a second semiconductor block 620. In some embodiments, the first semiconductor block 610 may have a first conductivity type, for example, p-type, and the second semiconductor block 620 may have a second conductivity type different from the first conductivity type, for example, n-type. In some embodiments, the second semiconductor block 620 may be in contact with the first semiconductor block 610 so that a P-N junction is formed. In some embodiments, the first semiconductor block 610 and the second semiconductor block 620 may include polysilicon. For example, the first semiconductor block 610 may be p-type polysilicon (p-poly), and the second semiconductor block 620 may be n-type polysilicon (n-poly).

In some embodiments, the first semiconductor block 610 may be electrically connected to the source electrode 540. In some embodiments, the second semiconductor block 620 may be electrically connected to the barrier layer 400 or the drain electrode 550. When the breakdown voltage of the diode structure 600 is relatively low, the second semiconductor block 620 may be electrically connected to the barrier layer 400 or the channel layer 300, so as to avoid damage to the diode structure 600. When the breakdown voltage of the diode structure 600 is relatively high, the second semiconductor block 620 may be electrically connected to the drain electrode 550. In other words, as the breakdown voltage of the diode structure 600 increases, the electrical connection position of the diode structure 600 may approach from the barrier layer 400 to the drain electrode 550.

In some embodiments, the diode structure 600 may further include a first doped region 611 and a second doped region 621. In some embodiments, the first doped region 611 may be formed on the insulating layer 570. Specifically, the first doped region 611 may be disposed on the insulating layer 570 and electrically connected to the source field plate 560. In some embodiments, the first doped region 611 is in contact with the first semiconductor block 610 and has the same conductivity type (that is, the first conductivity type) as the first semiconductor block 610. In some embodiments, the doping concentration of the first doped region 611 is greater than the doping concentration of the first semiconductor block 610. In some embodiments, the second doped region 621 may be formed on the insulating layer 570. Specifically, the second doped region 621 may be disposed on the insulating layer 570 and electrically connected to the barrier layer 400, the channel layer 300, or the drain electrode 550. In some embodiments, the second doped region 621 is in contact with the second semiconductor block 620 and has the same conductivity type (that is, the second conductivity type) as the second semiconductor block 620. In some embodiments, the doping concentration of the second doped region 621 is greater than the doping concentration of the second semiconductor block 620.

In some embodiments, the first connecting member 612 is formed to connect the first doped region 611 and the source electrode 540. In some embodiments, the second connecting member 622 is formed to connect the second doped region 621 and the barrier layer 400, or the second connecting member 622 is formed to connect the second doped region 621 and the channel layer 300, or the second connecting member 622 is formed to connect the second doped region 621 and the drain electrode 550. In some embodiments, the first connecting member 612 and the second connecting member 622 may include wires, interconnects, vias, the like, or a combination thereof. In some embodiments, the first connecting member 612 and the second connecting member 622 may include conductive materials.

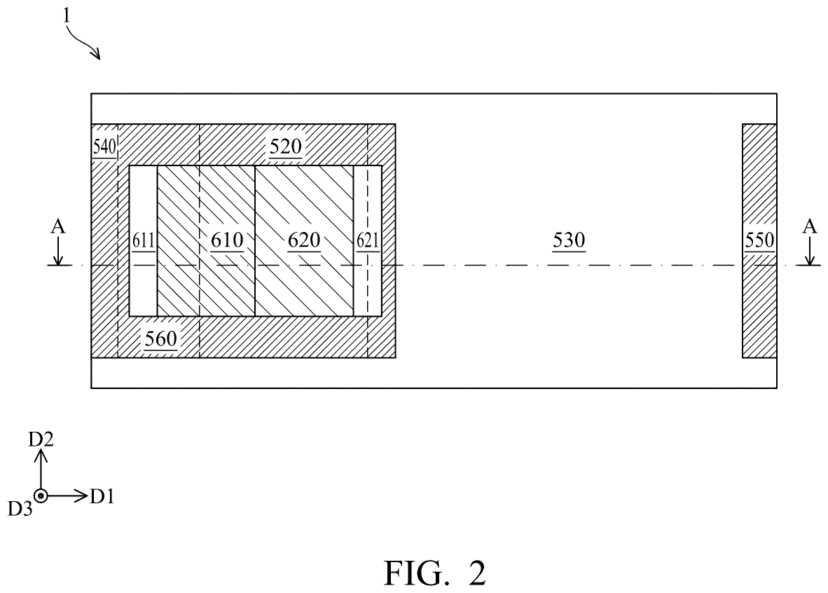

Referring to FIG. 2, it is the schematic top view of the semiconductor device 1 according to an embodiment of the present disclosure. Wherein, FIG. 1 is the schematic cross-sectional view taken along the cross-section A-A shown in FIG. 2. It should be noted that, for ease of understanding, some components of the semiconductor device 1 are omitted in FIG. 2, but the present disclosure is not limited thereto. As shown in FIG. 2, in some embodiments, the source electrode 540, the gate electrode 520, and the drain electrode 550 may be arranged along the first direction D1, and the first semiconductor block 610 and the second semiconductor block 620 may also be arranged along the first direction D1. In some embodiments, the gate electrode 520, the source electrode 540, the drain electrode 550, the first semiconductor block 610, and the second semiconductor block 620 extend along the second direction D2, respectively.

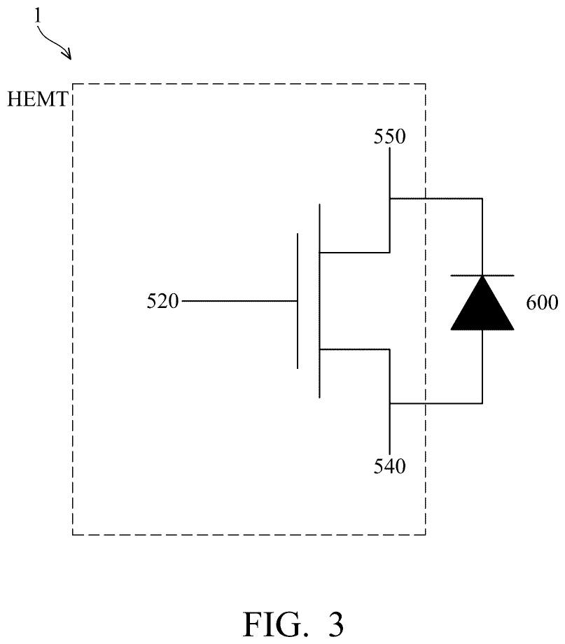

Referring to FIG. 3, it is the circuit diagram of the semiconductor device 1 according to an embodiment of the present disclosure. As shown in FIG. 3, the semiconductor device 1 may be regarded as the high electron mobility transistor HEMT electrically connected to the diode structure 600. In some embodiments, in the high electron mobility transistor HEMT, the gate electrode 520 controls the current flowing from the source electrode 540 to the drain electrode 550. In some embodiments, the source electrode 540 is connected to the anode terminal (also referred to as the p terminal) of the diode structure 600 (that is, the first semiconductor block 610), and the drain electrode 550 is connected to the cathode terminal (also referred to as n terminal) of the diode structure 600 (that is, the second semiconductor block 620). Therefore, the diode structure 600 provides unidirectional conduction to reduce power loss of the semiconductor device 1.

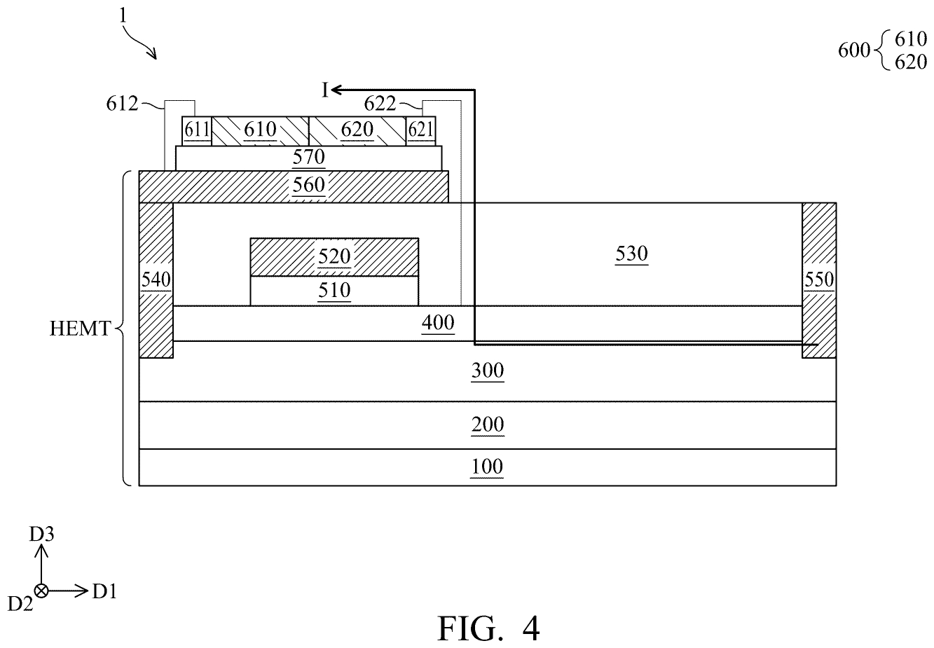

Referring to FIG. 4, it is the schematic diagram of a current path of the semiconductor device 1 according to an embodiment of the present disclosure. As shown in FIG. 4, the path of the current I in the semiconductor device 1 in the conduction state is shown. The current I may flow from the drain electrode 550 to the barrier layer 400 along the two-dimensional electron gas, and the current may be transmitted to the diode structure 600 via the second connecting member 622, but the diode structure 600 is not turned on (that is, the diode structure 600 is not conduct). In other words, when a positive voltage is applied to the drain electrode 550, the anode of the diode structure 600 is in a reverse biased, and no current flows to the anode of the diode structure 600. Therefore, high electron mobility transistor HEMT under the diode structure 600 may be operated normally.

Hereinafter, the same or similar reference numerals and descriptions are omitted.

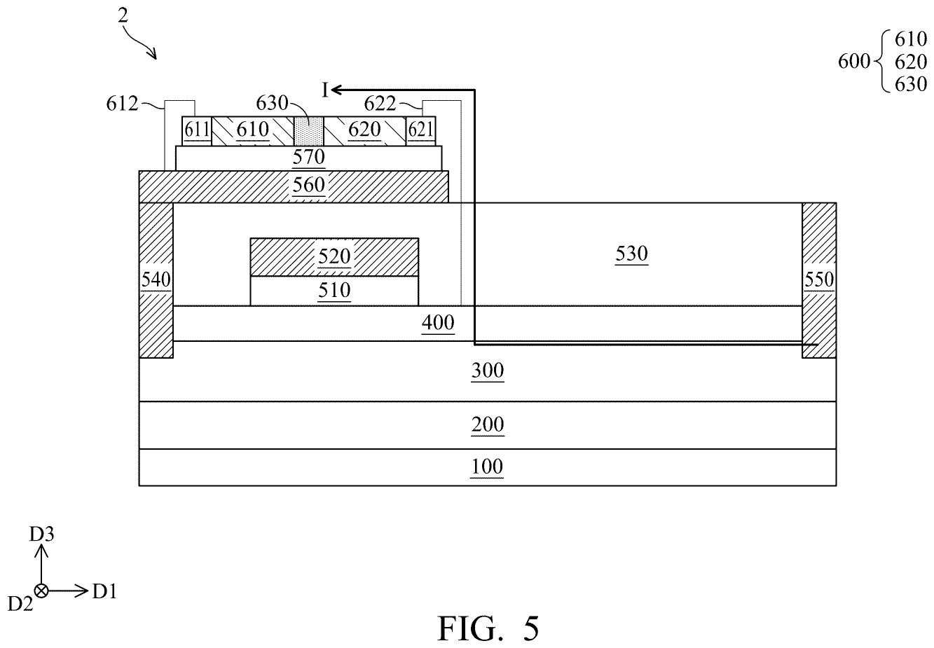

Referring to FIG. 5, it is the schematic cross-sectional view of a semiconductor device 2 according to an embodiment of the present disclosure. As shown in FIG. 5, the diode structure 600 is a P-I-N junction diode as an example for illustration, but the present disclosure is not limited thereto. In some embodiments, the diode structure 600 may further include an intrinsic semiconductor block 630. In some embodiments, the intrinsic semiconductor block 630 may be disposed between the first semiconductor block 610 and the second semiconductor block 620 and may be in contact with the first semiconductor block 610 and the second semiconductor block 620. In some embodiments, the intrinsic semiconductor block 630 may be a substantially undoped semiconductor material. In some embodiments, the intrinsic semiconductor block 630 may include polysilicon. As shown in FIG. 5, the current I may flow from the drain electrode 550 to the barrier layer 400 along the two-dimensional electron gas, and the current may be transmitted to the diode structure 600 via the second connecting member 622, but the diode structure 600 is not turned on. It should be noted that, the intrinsic semiconductor block 630 may further provide a depletion region, thereby increasing the breakdown voltage of the diode structure 600. Accordingly, it is possible to be applied in the high electron mobility transistor with high voltage.

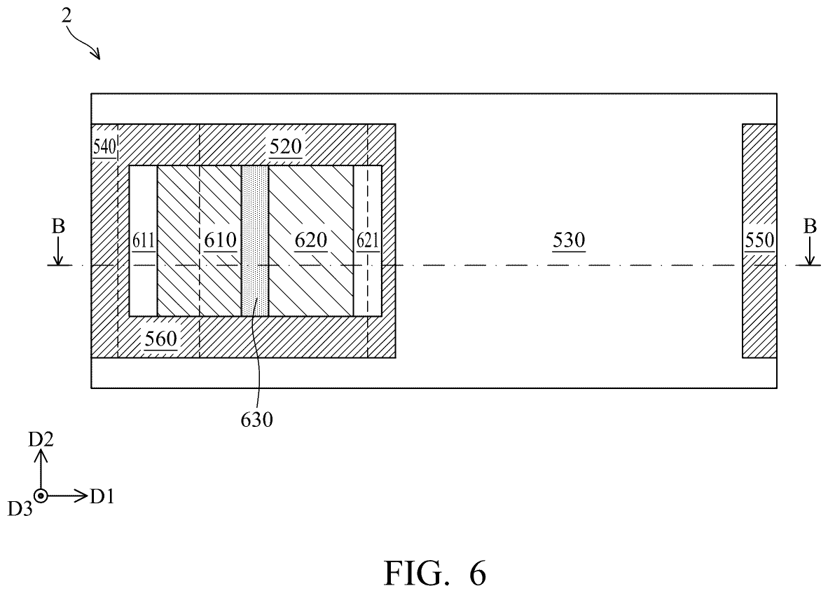

Referring to FIG. 6, it is the schematic top view of the semiconductor device 2 according to an embodiment of the present disclosure. Wherein, FIG. 5 is the schematic cross-sectional view taken along the cross-section B-B shown in FIG. 6. It should be noted that, for ease of understanding, some components of the semiconductor device 2 are omitted in FIG. 6, but the present disclosure is not limited thereto. As shown in FIG. 6, in some embodiments, the source electrode 540, the gate electrode 520, and the drain electrode 550 may be arranged along the first direction D1, and the first semiconductor block 610, the second semiconductor block 620, and the intrinsic semiconductor block 630 may be arranged along the first direction D1. In some embodiments, the gate electrode 520, the source electrode 540, the drain electrode 550, the first semiconductor block 610, the second semiconductor block 620, and the intrinsic semiconductor block 630 may extend along the second direction D2, respectively.

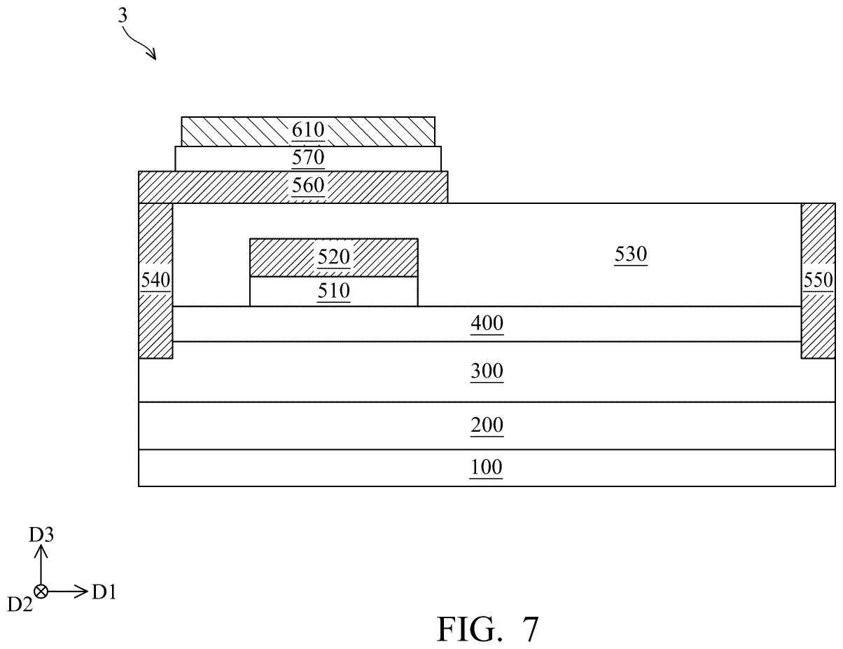

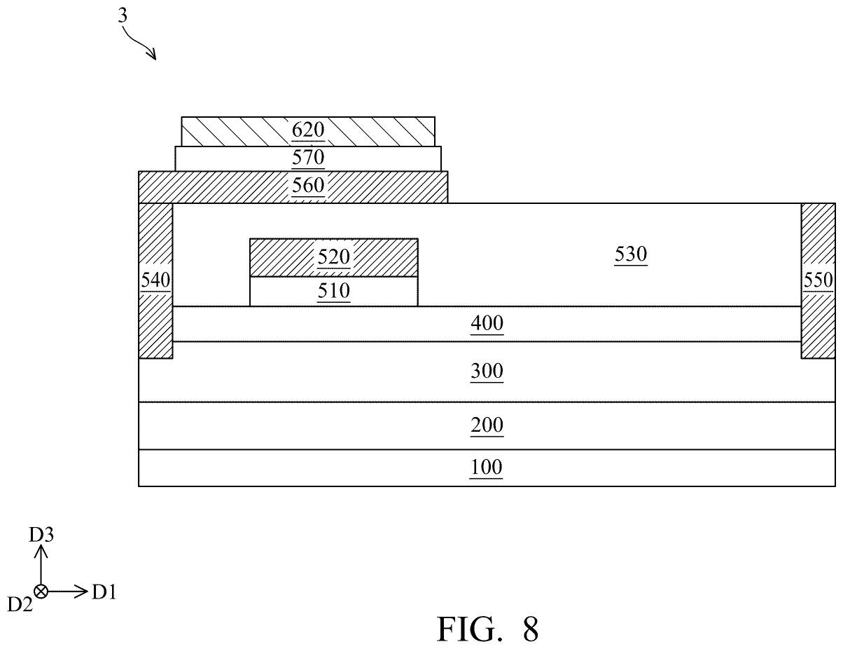

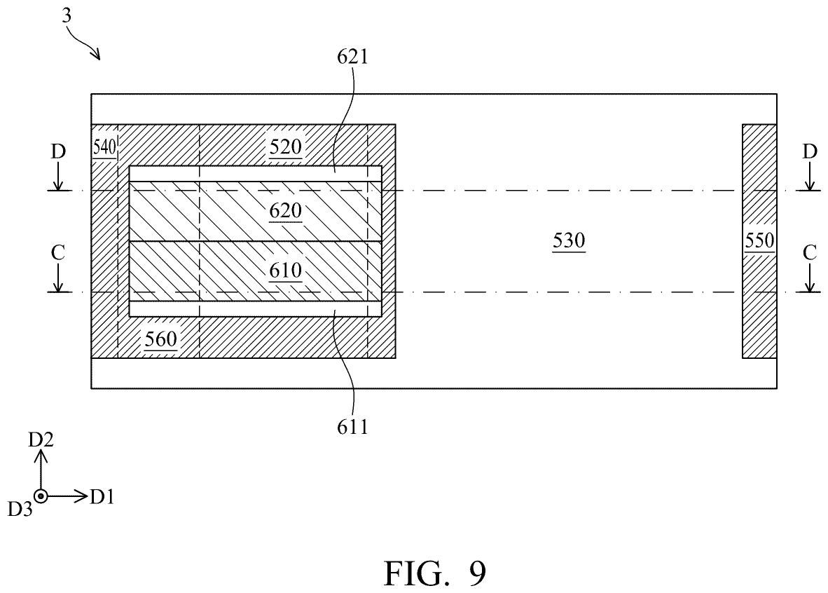

Referring to FIGS. 7 to 9. Wherein, FIGS. 7 and 8 are schematic cross-sectional views of a semiconductor device 3 according to an embodiment of the present disclosure, respectively, and FIG. 9 is the schematic top view of the semiconductor device 3 according to an embodiment of the present disclosure. Wherein, FIG. 7 is the schematic cross-sectional view taken along the cross-section C-C shown in FIG. 9, and FIG. 8 is the schematic cross-sectional view taken along the cross-section D-D shown in FIG. 9. It should be noted that, for ease of understanding, some components of the semiconductor device 3 are omitted in FIG. 9, but the present disclosure is not limited thereto.

As shown in FIG. 7, the first semiconductor block 610 may be disposed on the source field plate 560. As shown in FIG. 8, the second semiconductor block 620 may be disposed on the source field plate 560. As shown in FIG. 9, in some embodiments, the source electrode 540, the gate electrode 520, and the drain electrode 550 may be arranged along the first direction D1, and the first semiconductor block 610 and the second semiconductor block 620 may be arranged along the second direction D2 different from the first direction D1. In some embodiments, the gate electrode 520, the source electrode 540, and the drain electrode 550 extend along the second direction D2, respectively, and the first semiconductor block 610 and the second semiconductor block 620 extend along the first direction D1, respectively.

In other embodiments, the semiconductor device 3 may further include the intrinsic semiconductor block 630, and the first semiconductor block 610, the second semiconductor block 620, and the intrinsic semiconductor block 630 may be arranged along the second direction D2. In some embodiments, the intrinsic semiconductor block 630 may extend along the first direction D1.

In other embodiments, the method for forming a semiconductor device of the present disclosure may include providing the substrate 100. The method for forming the semiconductor device may include forming the channel layer 300 on the substrate 100 by the first epitaxial process; and forming the barrier layer 400 on the channel layer 300 by the first epitaxial process. The method for forming of the semiconductor device may include forming the gate electrode 520 on the barrier layer 400 by a metallization process; forming the dielectric layer 530 on the gate electrode 520; and forming the source electrode 540 and the drain electrode 550 on opposite sides of the gate electrode 520 by the metallization process, such that the source electrode 540 and the drain electrode 550 are in contact with the channel layer 300. The method for forming the semiconductor device may include forming the diode structure 600 on the dielectric layer 530 by the second epitaxial process after performing the metallization process, so that the diode structure 600 is electrically connected to the source electrode 540.

Accordingly, the present disclosure reduces the power loss in the conduction state by disposing the diode structure in the normal direction of the high electron mobility transistor. In addition, the overall area of the semiconductor device may be reduced, which is beneficial to increase the device density. For example, when the high electron mobility transistor HEMT is operated, the drain electrode in the high electron mobility transistor HEMT may be turned on with a negative voltage to generate leakage current. The semiconductor device of the present disclosure can provide the diode structure 600 electrically connected to the high electron mobility transistor HEMT, and make the diode structure 600 from the source electrode to the drain electrode of the high electron mobility transistor HEMT is in the conduction state, so as to quickly guide off the reverse conduction current to reduce power loss.

Components in the embodiments of the present disclosure can be arbitrarily combined as long as they do not violate the spirit of the disclosure or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a channel layer disposed on the substrate;
a barrier layer disposed on the channel layer;
a gate electrode disposed on the barrier layer;
a dielectric layer disposed on the gate electrode;
a source electrode and a drain electrode disposed on opposite sides of the gate electrode, respectively, and in contact with the channel layer, respectively;
a diode structure disposed on the dielectric layer and electrically connected to the source electrode.

2. The semiconductor device as claimed in claim 1, wherein the diode structure and the gate electrode at least partially overlap in a normal direction of the substrate.

3. The semiconductor device as claimed in claim 1, wherein the diode structure further comprises:
a first semiconductor block having a first conductivity type and electrically connected to the source electrode; and
a second semiconductor block having a second conductivity type different from the first conductivity type, in contact with the first semiconductor block, and electrically connected to the barrier layer, the channel layer, or the drain electrode.

4. The semiconductor device as claimed in claim 3, wherein the diode structure further comprises:
an intrinsic semiconductor block disposed between the first semiconductor block and the second semiconductor block, and in contact with the first semiconductor block and the second semiconductor block.

5. The semiconductor device as claimed in claim 3, wherein the diode structure further comprises:
a first doped region disposed on the dielectric layer, in contact with the first semiconductor block, and having the first conductivity type; and
a second doped region disposed on the dielectric layer, in contact with the second semiconductor block, and having the second conductivity type.

6. The semiconductor device as claimed in claim 5, wherein a doping concentration of the first doped region is greater than a doping concentration of the first semiconductor block, and a doping concentration of the second doped region is greater than a doping concentration of the second semiconductor block.

7. The semiconductor device as claimed in claim 3, wherein the source electrode, the gate electrode, and the drain electrode are arranged along a first direction, and the first semiconductor block and the second semiconductor block are arranged along the first direction.

8. The semiconductor device as claimed in claim 3, wherein the source electrode, the gate electrode, and the drain electrode are arranged along a first direction, and the first semiconductor block and the second semiconductor block are arranged along a second direction, wherein the second direction is different from the first direction.

9. The semiconductor device as claimed in claim 3, wherein the first conductivity type is P-type, and the second conductivity type is N-type.

10. The semiconductor device as claimed in claim 1, wherein the diode structure is a P-N junction diode, a P-I-N diode, a Schottky diode, or a combination thereof.

11. The semiconductor device as claimed in claim 1, wherein the diode structure is formed by an epitaxial process or a furnace process.

12. The semiconductor device as claimed in claim 1, wherein the diode structure is closer to the source electrode than to the drain electrode.

13. The semiconductor device as claimed in claim 1, further comprising:
a source field plate disposed on the dielectric layer, between the source electrode and the drain electrode, and electrically connected to the source electrode.

14. The semiconductor device as claimed in claim 13, wherein the source field plate is disposed between the diode structure and the gate electrode.

15. The semiconductor device as claimed in claim 13, wherein a projection of the diode structure on the substrate is located within a projection of the source field plate on the substrate.

16. The semiconductor device as claimed in claim 13, wherein a projection of the gate electrode on the substrate is located within a projection of the source field plate on the substrate.

17. The semiconductor device as claimed in claim 1, wherein a projection of the diode structure on the substrate at least partially overlaps a projection of the gate electrode on the substrate.

18. The semiconductor device as claimed in claim 1, wherein the diode structure comprises polysilicon.

19. The semiconductor device as claimed in claim 1, further comprising:
a compound semiconductor layer disposed between the barrier layer and the gate electrode.

20. The semiconductor device as claimed in claim 1, further comprising:
a buffer layer disposed between the substrate and the channel layer.
